(19) United States
(12) Patent Application Publication
(10) Pub. No.: US 2008/0308819 A1
(43) Pub. Date: Dec. 18, 2008

(54) Light-Emitting Diode Arrays and Methods of Manufacture

(75) Inventors: Hendrik Louwsma, Heerlen (NL); Pieter Goldhoorn, Veldhoven (NL); Hermans Jan, Landgraaf (NL)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: TPO DISPLAYS CORP., Miao-Li County (TW)

(21) Appl. No.: 11/763,475

(22) Filed: Jun. 15, 2007

(51) Int. Cl. H01L 33/00

(52) U.S. Cl. 257/89; 438/29; 257/E33.061; 257/E33.012

(57) ABSTRACT

Light-emitting diode arrays, methods of manufacture and displays devices are provided. A representative display device includes: a single LED element type having a single type of semiconductor stack; wherein color layers are located on a light output side of the semiconductor stack, and each color layer is arranged to convert radiation emitted by the single type semiconductor stack into radiation in either a red, a green or a blue portion of the electromagnetic spectrum in dependence on a position of the LED element within the display device.

### TECHNICAL FIELD

The present invention relates to light-emitting diode (LED) arrays and methods for manufacturing such arrays.

### DESCRIPTION OF THE RELATED ART

Nowadays, many display types exist, from conventional CRT (cathode ray tube) displays used for television and monitor applications to AM (active matrix) LCD (liquid crystal display) displays for television, monitor and mobile phone applications. The AM LCD's are emerging rapidly due to their form factor. Thin film transistor (TFT) technology enables a pixel array plate that allows for flat panel systems. The front-of-screen performance (contrast, brightness, viewing angle, switching times, uniformity, color gamut) of LCD displays is nevertheless still inferior to that of conventional CRT displays. The main reason is that the CRT is an emissive display type whereas the LCD is transmissive, reflective or both (transflective).

Flat panel array plates are also used in AM OLED (organic light emitting diode) displays that are currently in development. AM OLED displays are expected to give superior front-of-screen performance compared to AM LCD displays as AM OLED is an emissive display type too.

Niche markets are addressed by displays using electrophoresis, resulting in low power e-books with (often) static images. Very large screen displays, such as electronic billboards, may be made of arrays of LED elements, in which individual LED packages are placed on a carrier to form a display with very large pixel dimensions.

### SUMMARY

An embodiment of an LED array comprises: a base substrate and a plurality of light emitting diodes; the plurality of light emitting diodes being arranged on the base substrate as sub-pixels of a pixel matrix; a combination of sub-pixels, grouped as one pixel, comprising at least a first color type, a second color type and a third color type; each light emitting diode comprising a layer stack of a first contact layer, a semiconductor stack of a single type and a second contact layer; the semiconductor stack being on top of the first contact layer; the second contact layer being on top of the semiconductor stack; the single type semiconductor stack being arranged for emission of radiation in a light output direction; a color layer being located on the layer stack at the side of the light output direction of the semiconductor stack; the color layer being arranged for transforming the radiation emitted by the semiconductor stack into radiation of one of the at least first color type, second color type and third color type in correspondence with the color type of a position of the sub-pixel in the combination being grouped as one pixel.

An embodiment of a method for manufacturing an LED array comprises: providing a base substrate; providing on the base substrate a plurality of light emitting diodes as sub-pixels of a pixel matrix; a combination of sub-pixels, grouped as one pixel, comprising at least a first color type, a second color type and a third color type; each light emitting diode comprising a layer stack of a first contact layer, a semiconductor stack of a single type and a second contact layer; the semiconductor stack being on top of the first contact layer; the second contact layer being on top of the semiconductor stack; the single type semiconductor stack being arranged for emission of radiation in a light output direction; locating a color layer on the layer stack at the side of the light output direction of the semiconductor stack; the color layer being arranged for transforming the radiation emitted by the semiconductor stack into radiation of one of the at least first color type, second color type and third color type in correspondence with the color type of a position of the sub-pixel in the combination being grouped as one pixel.

An embodiment of a display device comprises: a single LED element type having a single type of semiconductor stack; wherein color layers are located on a light output side of the semiconductor stack, and each color layer is arranged to convert radiation emitted by the single type semiconductor stack into radiation in either a red, a green or a blue portion of the electromagnetic spectrum in dependence on a position of the LED element within the display device.

### BRIEF DESCRIPTION OF THE DRAWINGS

Below, the invention will be explained with reference to some drawings, which are intended for illustration purposes only and not to limit the scope of protection that is defined in the accompanying claims.

FIGS. 1a and 1b show a top view and a cross-section, respectively, of an exemplary layout of an embodiment of an LED array;

FIG. 2 shows schematically a cross-section of a first embodiment of an LED stack arrangement;

FIG. 3 shows schematically a cross-section of a second embodiment of an LED stack arrangement;

FIG. 4 shows schematically a cross-section of a third embodiment of an LED stack arrangement;

FIG. 5 shows an embodiment of a first circuit for driving an LED element.

### DETAILED DESCRIPTION

In an exemplary embodiment, an LED array display is provided which is arranged on a base substrate as a carrier for a plurality of LED elements that make up the LED array. The LED elements are manufactured on the base substrate by using deposition technology (technologies) and lithography.

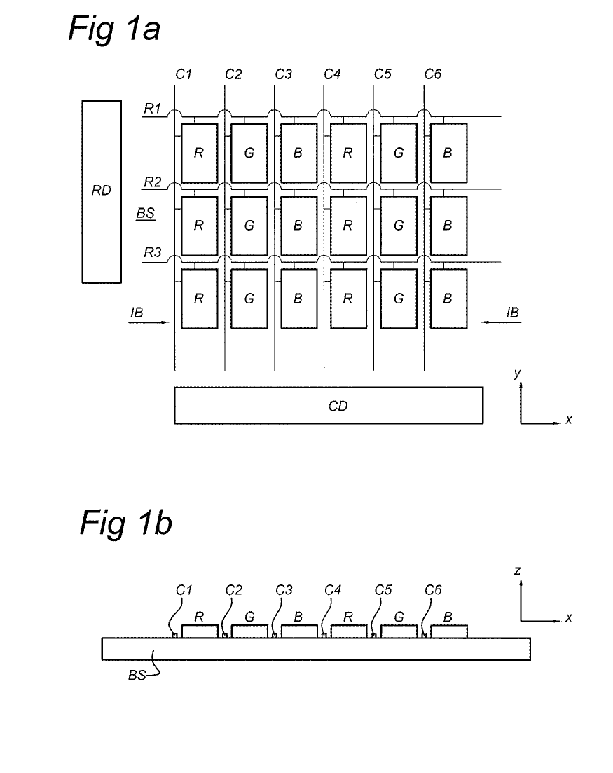

FIGS. 1a and 1b show a top view and a cross-section, respectively, of an exemplary layout of an embodiment of an LED array. Specifically, FIG. 1a shows the top view of an exemplary array of LED elements R, G, B in which LED elements of the same color are ordered in stripes.

The LED array, which comprises a plurality of light emitting diodes, is arranged in a pixel matrix. The pixel matrix comprises addressable pixels for forming an image. Each light emitting diode is a sub-pixel of one of the three color types R, G, B. A combination of sub-pixels, comprising the three color types R, G, B, are grouped as one pixel. In this exemplary case, the ordering of the R, G, B sub-pixels is in a so-called RGB stripe arrangement. Other RGB sub-pixel arrangements are also possible. The LED elements R, G, B are located on a base substrate BS. In FIG. 1a, a red LED element R is in the horizontal direction X adjacent to green LED element G. Green LED element G is next to blue element B. The sequence of R, G, B LED elements is repeated along the horizontal direction X.

On the substrate, interconnection circuitry for connecting the LED elements is provided. The LED elements of the array are each coupled with one terminal (not shown) to a first interconnection wire that extends as row line R1, R2, R3 in the horizontal direction X and with another terminal (not shown) to a second interconnection wire that extends as a column line C1, C2, C3; C4, C5, C6 in the vertical direction Y.

The row lines are connected to a row driving circuit RD and the column lines are connected to a column driving circuit CD. The row driving circuit RD and the column driving circuit CD are arranged for selectively addressing each LED element in the array.

Each LED element comprises a driving circuit for driving the LED element so as to emit radiation in an ‘on’ state. For reason of clarity, the electronic circuitry connecting to the LED elements is not shown in detail here. An example of a driving circuit is shown in FIG. 5.

FIG. 1b shows the cross-section of the LED array along horizontal line IB-IB of FIG. 1a. In this regard each two adjacent LED elements R, G, B are separated from each other by one column line. The LED elements R, G, B are arranged directly on the base substrate BS, which will be explained in more detail below.

To generate a specific color, each LED element or sub-pixel requires a different specific semiconductor stack ST, since the color generated by an LED element depends on the bandgap energy of the materials in the semiconductor stack. For example, a semiconductor stack of AlGaAs can generate radiation in the red portion of the electromagnetic spectrum, a stack of AlGaInP can generate radiation in the green/amber portion of the spectrum and a stack of AlGaInN can generate radiation in the green/blue portion of the spectrum. Other semiconductor stacks may be available for generating red, green or blue light.

It is recognized that the wavelength(s) of the viewable radiation of a LED element R; G; B may be controlled not just by the specific bandgap energy of the semiconductor stack but alternatively also by means of luminescence of a color layer that is covering the semiconductor stack in the direction of the light output of the semiconductor stack. Luminescence of the color layer relates to a property of the color layer to absorb radiation emitted by the LED semiconductor stack and to emit radiation with a relatively longer wavelength.

In this exemplary embodiment only a single LED element type is needed with just one single type of semiconductor stack. Suitable color layers are located on the light output side of the semiconductor stack. Each color layer is arranged to convert the radiation emitted by the single type semiconductor stack into radiation in either the red, green or blue portion of the electromagnetic spectrum in dependence on the position of the LED element within the display device. Advantageously, the set-up of a single semiconductor stack and color layers in such an embodiment results in a relatively simple manufacturing method of the LED array.

It is noted that each of the LED elements R, G, B is formed by a sequence of semiconductor manufacturing processes. Such semiconductor manufacturing processes comprise a variety of processing steps, such as application of a photosensitive layer, patterning of such a layer by exposure to radiation and subsequent removal of exposed (or not-exposed) material to form a patterned mask layer. Further, the processes may comprise vapor deposition technology (either physical or chemical), and/or atomic layer growth (for example, molecular beam epitaxy). Also, the processes may comprise etching (dry and/or wet) and chemical mechanical polishing. Additionally, the processes may comprise ion-implantation technology. Persons skilled in the art will appreciate which combinations of the semiconductor manufacturing processes to apply to manufacture an LED array, with such processes potentially varying among various embodiments.

In one embodiment, the LED element may comprise a single type semiconductor stack with a bandgap energy that allows emission of radiation in the ultraviolet (UV) range of the electromagnetic spectrum. The color layers on the LED elements are arranged to transform the UV radiation in either red, green or blue depending on the position of the LED element within the LED array. In another embodiment, the single type semiconductor stack may be arranged for emission of radiation in a wavelength range, within the spectrum range visible to the human eye.

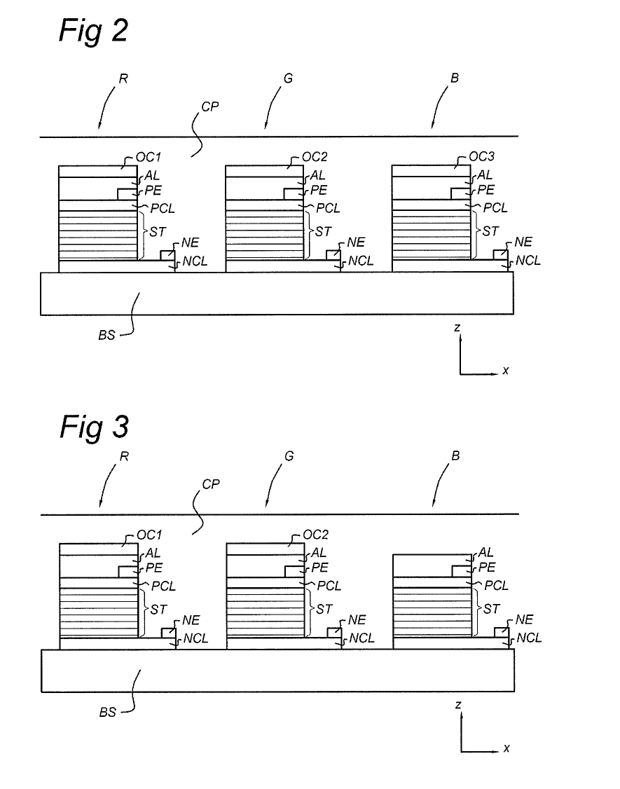

FIG. 2 shows schematically a cross-section of a first embodiment of an LED stack arrangement. The cross-section extends along the horizontal direction X. As shown in FIG. 2, LED elements R, G, B are arranged adjacent to each other on a base substrate BS. The base substrate BS in this embodiment is a specific substrate that has a specific structural orientation which allows the semiconductor stack of the LED elements to be substantially epitaxial with the base structure.

Each LED element R, G, B is constructed as a layer stack in the direction Z and comprises a negative contact layer NCL. The negative contact layer NCL is attached to the base substrate BS by a process of either lamination or deposition (the light output is directed away from the surface of the base substrate BS). A negative electrode NE is located on the negative contact layer NCL. The single type semiconductor stack ST is located on top of the negative contact layer of the LED element R, G, B.

Optionally, a distributed Bragg reflector (DBR) layer for adjusting the light output direction of the LED element is implemented in an LED element. The DBR layer is arranged to direct the light emitted by the semiconductor stack in substantially one direction. The location of the DBR layer is typically at a side of the semiconductor stack facing away from the intended light output direction. The DBR layer may, for example, be located between the negative contact layer and the semiconductor stack.

The single type semiconductor stack ST has a bandgap energy that allows the LED element to emit radiation in a specific range of the electromagnetic spectrum, e.g., the ultraviolet range.

A positive contact layer PCL is located on top of each semiconductor stack ST. Each positive contact layer PCL is coupled to a respective positive electrode PE. Above the positive contact layer PCL and its respective positive electrode PE, an adjustment layer AL may be located for improvement of the optical characteristics of the respective LED element.

As a top layer of each LED element, a color layer OC1, OC2, OC3 is provided. Each color layer OC1, OC2, OC3 is arranged to transform the radiation emitted by the single type semiconductor stack ST into radiation with a wavelength (or wavelengths) in one of the red R, green G and blue B portions of the visible electromagnetic spectrum. For example, the color layer OC1 is arranged to transform the emitted radiation of the semiconductor stack ST into radiation in the red portion R, the color layer OC2 is arranged to transform into the green portion G, and the color layer OC3 for a transform into the blue portion B of the electromagnetic spectrum.

For example, each color layer OC1, OC2, OC3 may comprise phosphors to transform the radiation emitted by the single type semiconductor stack ST to either red, green or blue. The phosphors may be applied on the LED elements by a screen printing process, for example. A further advantage of using phosphors is that the color produced by each color layer OC1, OC2, OC3 can be customized for a particular application of the display device comprising the LED array according to this embodiment.

An overall capping layer CP may be provided that covers the LED elements R, G, B for protection of the LED elements from the environment and reduce possible corrosion. Additionally, the capping layer CP may comprise one or more sub-layers, such as a diffuser sub-layer for diffusion of light originated by the LED element R, G, B and/or an anti-reflection sub-layer. Other sub-layers that may improve the optical performance of each LED element are also conceivable.

A color layer may also have the function of adapting the color of the radiation emitted by the semiconductor stack to a better perceived color. For example, the semiconductor stack ST is arranged for emission of radiation in a blue portion of the spectrum. The color layers OC1, OC2 of the red and green sub-pixel LED elements R, G are arranged for transforming the radiation emitted by the semiconductor stack to red and green color, respectively. The color layer OC3 of the blue sub-pixel is arranged to adapt the blue color to a better perceived blue color.

FIG. 3 shows schematically a cross-section of a second embodiment of an LED stack arrangement. In FIG. 3, the same elements as shown in FIG. 2 are assigned the same reference numbers. In this second embodiment, the single type semiconductor stack may be arranged for emission of radiation in one wavelength range, within the spectrum range visible to the human eye. In the example shown here, the single type semiconductor stack ST is arranged for emission of radiation of a blue color.

The LED elements R, G of the red and green sub-pixel, respectively, comprise the same semiconductor stack for emission of radiation of blue color (in this example). On top of the semiconductor stack at the side of the light output, a color layer OC1, OC2 is arranged for transformation of the radiation emitted by the single type semiconductor stack ST to red and green, respectively.

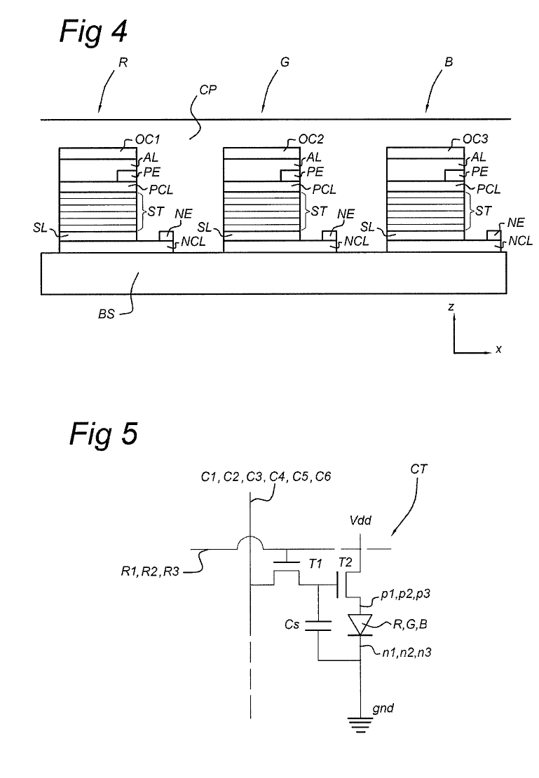

FIG. 4 shows schematically a cross-section of a third embodiment of an LED stack arrangement. The cross-section extends along the horizontal direction X.

On a base substrate BS, LED elements R, G, B are arranged adjacent to each other. Each LED element R, G, B is constructed as a layer stack and comprises a negative contact layer NCL on which an adhesion/precursor layer SL is located between the negative contact layer and the semiconductor stack ST. By using such an adhesion/precursor layer SL as a specific substrate, the semiconductor stack ST can be accommodated on the negative contact layer in case the (crystalline) structure of the negative contact layer does not allow a direct formation or growth of the semiconductor stack ST on the negative contact layer.

On a portion of the negative contact layer, a negative electrode NE is located. On top of the adhesion/precursor layer SL of the LED element R, G, B the semiconductor stack ST is located.

On top of each semiconductor stack ST a positive contact layer PCL is located. Each positive contact layer PCL is connected to a respective positive electrode PE. Optionally, an adjustment layer AL may be located above the positive contact layer PCL and its respective positive electrode PE depending on the optical characteristics of the LED element.

Finally, on top of the layer stack, the color layer OC1, OC2, OC3 is provided. In some embodiments the relative positions of the adhesion/precursor layer SL and the negative contact layer NCL may be exchanged. The adhesion/precursor layer SL is then located on the base substrate and the negative contact layer NCL is located on top of the adhesion/precursor layer.

By using such an adhesion/precursor layer SL as a substrate layer, the LED array can be constructed on a base substrate which can be large in size and low in cost. In this case, it is not required that the base substrate has a suitable surface condition (i.e., a crystal lattice) that allows the (direct) formation/growth of the semiconductor stack of the LED element.

FIG. 5 shows, as an example, an embodiment of a first circuit for driving an LED element of an embodiment of an LED array display device. The circuit CT of this embodiment comprises a selection line SEL, a data line DATA and a supply line Vdd, a first transistor T1, a second transistor T2, and a storage capacitor CS.

The first and second transistors are typically embodied as thin-film transistors (TFT). The selection line SEL extends as row line R1, R2, R3 and is coupled to the gate of the first thin film transistor T1. The data line DATA extends as column line C1; C2, C3, C4, C5, C6 and is coupled to a source of the first transistor T1. A drain of the first transistor T1 is coupled to a gate of the second transistor T2 and to a first terminal of the storage capacitor CS.

The supply line Vdd couples to a source of the second transistor T2. A drain of the second transistor T2 is coupled to the positive electrode P1, P2, P3 of the LED element R, G, B. Additionally, a second terminal of the storage capacitor CS is coupled to the negative electrode N1; N2; N3 of the LED element and to ground GND.

During use, a gate selection pulse on the SEL line opens TFT T1, enabling a data voltage on the DATA line, of which the voltage level corresponds to the light output of the LED element, to be stored on the storage capacitor CS. The voltage across the storage capacitor CS controls the gate of the second transistor T2 and opens second TFT T2, also after first TFT T1 has closed again. The LED element is driven by the supply line Vdd during the frame time. At the next selection pulse on SEL, a similar or different data voltage (on DATA) may be put on the storage capacitor CS, which may change the LED current correspondingly. A potential drawback of this simple circuit CT is that the LED current and hence the LED light output directly depend on a threshold voltage of the second TFT T2.

To overcome this drawback, a compensation circuit for compensating the threshold voltage of the second transistor T2 may be incorporated in the driving circuit CT. Various compensation circuits for compensating the threshold voltage of the second transistor T2 can be used such as current-controlled and voltage-controlled compensation circuits. These compensation circuits can typically comprise 4 to 6 (thin-film) transistors.

The aperture ratio of a sub-pixel R, G, B is not an issue for a LED array that is an emissive display type. The TFT circuit CT with storage capacitor CS can be placed either adjacent to each individual LED element, or underneath the LED element or partially adjacent and underneath the LED element.

The interconnection of the individual LED devices to shared row and column electrodes can be established in several ways. Above, an LED stack arrangement has been described in which the negative electrodes are formed one or more steps prior to the formation step of the positive electrodes. This directs the order of the semiconductor layers and consequently the preferred light output direction (in FIGS. 2, 3 and 4, the preferred light output direction is substantially upward along the Z-direction). As will be appreciated by the skilled person, in case the substrate is transparent, one may also reverse the order of the positive and negative electrodes and the stacking order of the semiconductor stack in relation to the position of the base substrate, and hence the preferred light output direction. A side of the transparent substrate facing away from the side where the LED element(s) is (are) located, may comprise the adjustment layer(s) and/or the diffuser sub-layer and/or the anti-reflection sub-layer and/or other sub-layer(s) that may improve the optical performance of the LED element(s). A DBR layer may be provided (above the semiconductor stack relative to the substrate) to direct the light output in a direction through the substrate.

Furthermore, an LED array may comprise at least one additional type of LED element next to the types of LEDs that produce radiation of red, green or blue color. For example, next to the red, green and blue color LED elements, the LED array may comprise LED elements of a type that produces substantially white radiation by means of a suitable color layer (RGBW LED). Such a suitable color layer may comprise phosphors arranged for a transformation of the radiation emitted by the semiconductor stack into “white” radiation.

It is noted that the efficiency of a color layer to transform the radiation generated by the semiconductor stack into radiation of that color may differ from one color to another color. In that respect, colors generated by a set of sub pixels (RGB or for example RGBW) may suffer from a deviation due to an imbalance of luminance between sub-pixels. To provide a correction, the area size of each sub-pixel can be chosen during manufacturing in such a way that imbalance of luminance between sub-pixels is corrected. For example, if a red color radiation emitted by the red color layer R has a relatively low intensity in comparison to the green and/or blue color, the area size of the red color LED element R can be chosen larger than the area size of the green and/or blue LED element, to compensate for the difference in intensity of the respective sub-pixels.

Advantageously, at least some embodiments involve a display device on which only a single LED element type with just one single type of semiconductor stack needs to be created. Suitable color layers are located on the light output side of the semiconductor stack. Each color layer is arranged to convert the radiation emitted by the single type semiconductor stack into radiation in either the red, green or blue portion of the electromagnetic spectrum in dependence on the position of the LED element within the display device. This set-up of a single semiconductor stack and color layers results in a relatively simple manufacturing method of the LED array.

It should be emphasized that the above-described embodiments are merely possible examples of implementations set forth for a clear understanding of the principles of the invention. Many variations and modifications may be made to the above-described embodiments without departing substantially from the spirit and principles of the invention. All such modifications and variations are intended to be included herein within the scope of this disclosure and the present invention and protected by the following claims.

1. An LED array comprising:
a base substrate and a plurality of light emitting diodes;
the plurality of light emitting diodes being arranged on the base substrate as sub-pixels of a pixel matrix;
a combination of sub-pixels, grouped as one pixel, comprising at least a first color type, a second color type and a third color type;
each light emitting diode comprising a layer stack of a first contact layer, a semiconductor stack of a single type and a second contact layer;
the semiconductor stack being on top of the first contact layer;
the second contact layer being on top of the semiconductor stack;
the single type semiconductor stack being arranged for emission of radiation in a light output direction;
a color layer being located on the layer stack at the side of the light output direction of the semiconductor stack;
the color layer being arranged for transforming the radiation emitted by the semiconductor stack into radiation of one of the at least first color type, second color type and third color type in correspondence with the color type of a position of the sub-pixel in the combination being grouped as one pixel.

2. LED array according to claim 1, wherein the LED array further comprises interconnection circuitry on the substrate, operative to connect the light emitting diodes of the array for addressing each of the light emitting diodes.

3. LED array according to claim 1, wherein the radiation, after being transformed by the color layer, has a longer wavelength than the radiation emitted by the semiconductor stack.

4. LED array according to claim 1, wherein the color layer comprises phosphors of one of at least a first, a second and a third type for transforming the radiation emitted by the semiconductor stack into radiation of the one of the at least a first, a second and a third color type.

5. LED array according to claim 1, wherein the semiconductor stack is arranged for emission of radiation in the ultraviolet range of the electromagnetic spectrum.

6. LED array according to claim 1, wherein the layer stack is located on the surface of the base substrate.

7. LED array according to claim 6, wherein each light emitting diode further comprises an adhesion/precursor layer and the adhesion/precursor layer is arranged between the base substrate and the layer stack.

8. LED array according to claim 7, wherein each light emitting diode further comprises an adjustment layer; the adjustment layer being arranged between the semiconductor stack and the color layer.

9. LED array according to claim 1, wherein the first contact layer is a negative contact layer and the second contact layer is a positive contact layer.

10. LED array according to claim 1, wherein the first contact layer is a positive contact layer and the second contact layer is a negative contact layer.

11. LED array according to claim 1, wherein the plurality of light emitting diodes is embedded in an overall capping layer.

12. LED array according to claim 1, wherein the light emitting diode comprises a distributed Bragg reflector layer operative to adjust a light output direction of the light emitting diode.

13. A method for manufacturing an LED array comprising:
providing a base substrate;
providing on the base substrate a plurality of light emitting diodes as sub-pixels of a pixel matrix; a combination of sub-pixels, grouped as one pixel, comprising at least a first color type, a second color type and a third color type;
each light emitting diode comprising a layer stack of a first contact layer, a semiconductor stack of a single type and a second contact layer; the semiconductor stack being on top of the first contact layer; the second contact layer being on top of the semiconductor stack; the single type semiconductor stack being arranged for emission of radiation in a light output direction;
locating a color layer on the layer stack at the side of the light output direction of the semiconductor stack; the color layer being arranged for transforming the radiation emitted by the semiconductor stack into radiation of one of the at least first color type, second color type and third color type in correspondence with the color type of a position of the sub-pixel in the combination being grouped as one pixel.

14. Method according to claim 13, further comprising:
providing interconnection circuitry on the substrate, for connection to the light emitting diodes of the array for addressing each of the light emitting diodes.

15. Method according to claim 13, wherein the color layer comprises phosphors of one of at least a first, second and third type for transforming the radiation emitted by the semiconductor stack into radiation of the one of the at least first, second and third color type.

16. Method according to claim 13, wherein the semiconductor stack is arranged for emission of radiation in the ultraviolet range of the electromagnetic spectrum.

17. Method according to claim 13, wherein the color layer is applied on the single type semiconductor stack by a screen printing process.

18. Method according to claim 13, further comprising:
providing an adhesion/precursor layer between the base substrate and the semiconductor stack.

19. Method according to claim 13, further comprising:
providing an adjustment layer between the semiconductor stack and the color layer.

20. A display device comprising:
a single LED element type having a single type of semiconductor stack;
wherein color layers are located on a light output side of the semiconductor stack, and each color layer is arranged to convert radiation emitted by the single type semiconductor stack into radiation in either a red, a green or a blue portion of the electromagnetic spectrum in dependence on a position of the LED element within the display device.
